(19) United States
(12) Patent Application Publication
(10) Pub. No.: US 2026/0304685 A1
(43) Pub. Date: Oct. 1, 2026

(54) SERVER SLAVE-FAN CONTROL

(71) Applicant: AMD Design, LLC, Wilmington, DE (US)

(72) Inventors: TingYu Tony LIN, Fairfield, NJ (US); Felix Fang Ning LIU, Flushing, NY (US); Chaunke LIN, Secaucus, NJ (US)

(73) Assignee: AMD Design, LLC, Wilmington, DE (US)

(21) Appl. No.: 19/092,230

(22) Filed: Mar. 27, 2025

(51) Int. Cl. H05K 7/20; G06F 1/20

(52) U.S. Cl. CPC H05K 7/20209; G06F 1/20; H05K 7/20172; H05K 7/20727; G06F 2200/201

(57) ABSTRACT

A server includes a master fan configured to generate airflow through the server and a slave fan disposed proximate a heat-generating component in the server. An operation of the slave fan is controlled, based on an operation of the master fan, by a slave fan controller communicatively coupled with the master fan and the slave fan.

### BACKGROUND

The present disclosure generally relates to the field of data centers and server systems, more particularly, to mitigating heat generation and dissipation within components of a server.

Server systems are widely used to support a variety of applications, from cloud computing to high-performance processing. These systems typically consist of multiple components, such as processors, memory, storage devices, and power supplies, all of which generate significant amounts of heat during operation. The heat produced by these components, especially in high-density configurations, can lead to several issues, including premature failure of sensitive electronic components (e.g., CPUs, GPUs, memory modules) and reduced component lifespan.

Modern servers, including those used in cloud computing, artificial intelligence (AI), machine learning (ML), networking, blockchain, and storage applications, are performing more tasks than ever before and, as a result, are generating more heat. Typically, fans are used to circulate air through the server system and remove the heat generated by the components therein. Even in water-cooled servers, fans are often used to cool secondary components (e.g., power supplies, storage drives). As such, the movement of air within the server or its internal components is critical for maintaining optimal temperatures and cooling efficiency, ensuring that heat is dissipated properly to prevent overheating and maintain reliable system performance.

Certain operations, such as replacing or adding components without powering down the system (known as “hot swap” events), can disrupt the airflow within the server. For example, many operations involve removing or raising a cover of a server, which disrupts airflow through the server. This airflow disruption can hinder the cooling efficiency, potentially affecting system health and leading to thermal issues that may reduce the lifespan or reliability of components. Properly managing airflow during these service events can be crucial to maintaining the stability of the server's cooling system and preventing overheating of critical components.

All of the subject matter discussed in the Background section is not necessarily prior art and should not be assumed to be prior art merely as a result of its discussion in the Background section. Along these lines, any recognition of problems in the prior art discussed in the Background section or associated with such subject matter should not be treated as prior art unless expressly stated to be prior art. Instead, the discussion of any subject matter in the Background section should be treated as part of the inventor’s approach to the particular problem, which, in and of itself, may also be inventive.

### SUMMARY

According to an embodiment of the present disclosure, a server is described herein. The server includes a master fan configured to generate airflow through the server. A slave fan is disposed proximate a heat-generating component in the server. The server further includes a slave fan controller communicatively coupled with the master fan and the slave fan configured to control an operation of the slave fan based on an operation of the master fan.

According to another embodiment of the present disclosure, a computer-implemented method for controlling a slave fan of a server is described herein. The computer-implemented method includes determining, by a slave fan controller that is separate from a master fan controller, an operational speed of a master fan of the server that is controlled by the master fan controller, and controlling, by the slave fan controller and based on the operational speed of the master fan, the slave fan.

According to yet another embodiment of the present disclosure, a slave fan controller is described herein. The slave fan controller is configured to be disposed within a server and include a processing unit configured to: determine an operational speed of a master fan of the server, and control, based on the operational speed of the master fan, a slave fan of the server. The master fan being configured to move air through the server, and the slave fan being configured to move air proximate a heat-generating component of the server.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

The following detailed description, given by way of example and not intended to limit the embodiments described herein, will best be appreciated in conjunction with the accompanying drawings, in which:

FIG. 1 depicts a simplified plan view of a server, according to an embodiment of the present disclosure;

FIG. 2 depicts components of a cooling system, according to an embodiment of the present disclosure;

FIG. 3 depicts an example configuration of a master fan and a slave fan, according to an embodiment of the present disclosure;

FIG. 4 depicts a functional block diagram illustrating components of a slave fan controller, according to an embodiment of the present disclosure;

FIG. 5 depicts a flowchart illustrating the steps of a computer-implemented method for controlling the operation of slave fan, according to an embodiment of the present disclosure;

FIG. 6 depicts a flowchart illustrating the steps of a computer-implemented method for controlling the operation of slave fan, according to an embodiment of the present disclosure; and

FIG. 7, depicts a functional block diagram depicting an example of a system used to control an operation of the slave fan, according to an embodiment of the present disclosure.

The drawings are not necessarily to scale. The drawings are merely schematic representations, not intended to portray specific parameters of the embodiments in the present disclosure. The drawings are intended to depict typical embodiments of the present disclosure. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. The claimed structures and methods may, however, be embodied in many different forms and should not be construed as limited to the exemplary embodiments set forth herein. In the description, details of various conventional features and techniques may be omitted to avoid unnecessarily obscuring the presented embodiments.

During hot swap service events in servers, where components are replaced without powering down the system, airflow inside the server can be disrupted (e.g., due to a lid or cover being removed or raised). This change in airflow can result in insufficient cooling for certain heat-generating components, leading to overheating. Increasing the fan speed as a solution to inadequate cooling may not effectively restore proper cooling and can introduce additional issues like error logs, increased fan noise, and higher energy consumption. Furthermore, due to limited space on the server motherboard, there is often no room for extra fans or active heat sinks to improve cooling for individual components.

The consequences of airflow disruptions can be significant. Overheating can reduce the Mean Time Between Failures (MTBF) of components, increase the Annual Failure Rate (AFR), and potentially trigger thermal trips, causing the system to shut down to protect sensitive hardware. These factors not only affect system reliability and component lifespan but also increase operational costs, making it crucial to address these challenges for better server performance and longevity.

Therefore, embodiments of the present disclosure introduce a server slave fan control system in which a slave fan is installed in localized areas of a server system proximate to a heat-generating component for providing targeted cooling. In an embodiment, the slave fan is significantly smaller than a master fan of the server, allowing it to be placed close to heat-generating components for efficient, localized airflow, particularly during service events. The slave fan is configured to operate based on an operation of the master fan, ensuring seamless integration of the slave fan into the server’s cooling system. Accordingly, the proposed slave fan control system provides effective cooling of critical components without the need for additional power sources or complex modifications to the system’s infrastructure.

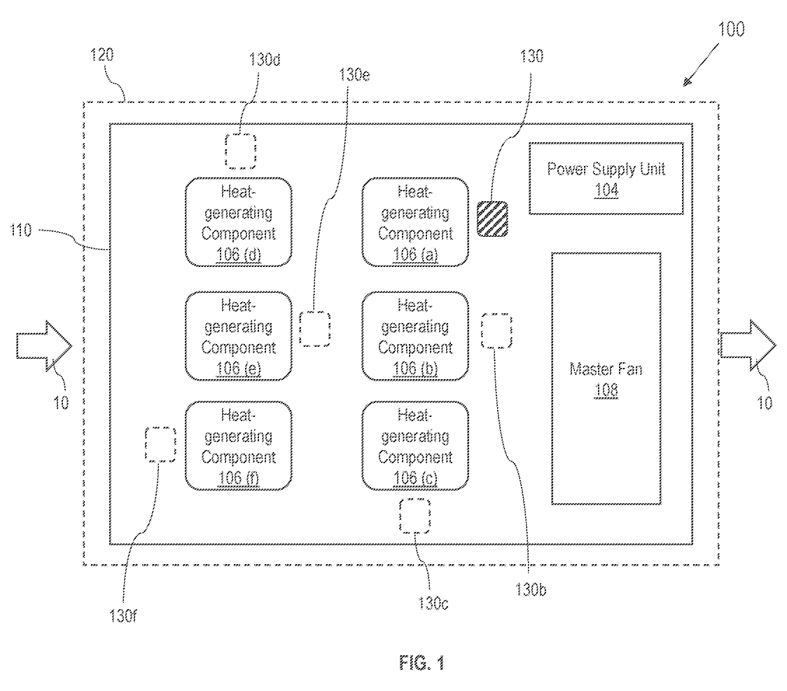

Embodiments by which the server slave fan control system can be implemented are described in detail below by referring to the accompanying drawings in FIGS. 1-7.

Referring now to FIG. 1, a simplified plan view of a server 100 is shown, according to an embodiment of the present disclosure. In this embodiment, server 100 includes a master fan 108 that is operatively connected to a power supply unit (PSU) 104, which provides power to the master fan 108. The master fan 108 may include any number of fans therein. Furthermore, the master fan 108 may include a plurality of fans that are distributed throughout the server 100.

Server 100 further includes a plurality of heat-generating components 106 (e.g., 106a, 106b, 106c, 106d, 106e, and 106f). As used herein, the term “heat-generating component” refers to any electronic (hardware) component or part of server 100 that produces significant amounts of heat during operation. Heat-generating components 106 may include, but are not limited to, CPUs, GPUs, RAM, storage devices, and PSUs. In the embodiment depicted in FIG. 1, six heat-generating components 106 are shown for illustration purposes. However, it can be understood that server 100 may include any number of heat-generating components 106 (e.g., more or less than six), depending on the specific design and operational requirements of the system. Heat-generating components 106 may require cooling to maintain optimal performance and prevent overheating, which could lead to system instability, reduced lifespan, or failure. Thus, master fan 108 provides a cooling airflow 10 to cool heat-generating components 106 within the server 100.

In an embodiment, PSU 104, master fan 108, and heat-generating components 106 are mounted on a central circuit board 110, commonly referred to as motherboard. Central circuit board 140 coordinates communication between various components of server 100, including heat-generating components 106. In some cases, the central circuit board 140 itself may also generate heat, especially in high-performance or multi-core processor systems. The internal components of server 100, as depicted in FIG. 1, are housed within a cover 120. Cover 120 provides the physical enclosure or framework for all the internal components of server 100. Cover 120 offers structural support and protection, ensuring that the server’s internal parts are securely mounted, organized, and safeguarded from external factors such as dust, moisture, and physical damage. Components of server 100 can further include a slave fan 130 communicatively coupled with master fan 108. In an embodiment, slave fan 130 is configured to operate based on an operation of master fan 108, as will be explained in detail below.

In one or more embodiments, a location of slave fan 130 can be selected based on the likelihood of a heat-generating component 106 overheating during a service event. As shown in FIG. 1, potential locations of slave fans 130 are shown (e.g., slave fans 130b, 130c, 130d, 130e, and 130f), each corresponding to respective areas within server 100 (e.g., proximate respective heat-generating components 106. For instance, slave fan 130 can be used to directly cool heat-generating component 106(a), while slave fans 130b, 130c, 130d, 130e, and 130f can be used to target cooling of respective heat-generating components 106b, 106c, 106d, 106e, and 106f. It should be noted that, space permitting, multiple slave fans 130 can be positioned within server 100 to optimize cooling (e.g., proximate respective heat-generating components 106). Slave fans 130b, 130c, 130d, 130e, and 130f can be positioned in the same manner as slave fan 130 or differently, relative to the corresponding heat-generating component 106. For example, slave fans can be placed in front of, to the side of, or in other positions around the heat-generating components 106. Furthermore, not all heat-generating components 106 may receive a slave fan 130. Particular heat-generating components 106 may be especially susceptible to overheating during hot swap events. For the purpose of this disclosure, a single slave fan 130 is discussed (which may be used to cool one or more heat-generating components 106), however, any number of slave fans 130 may be used within the server 100 without departing from the scope of this disclosure.

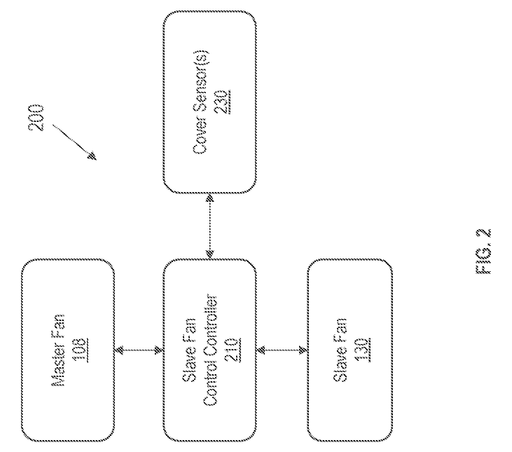

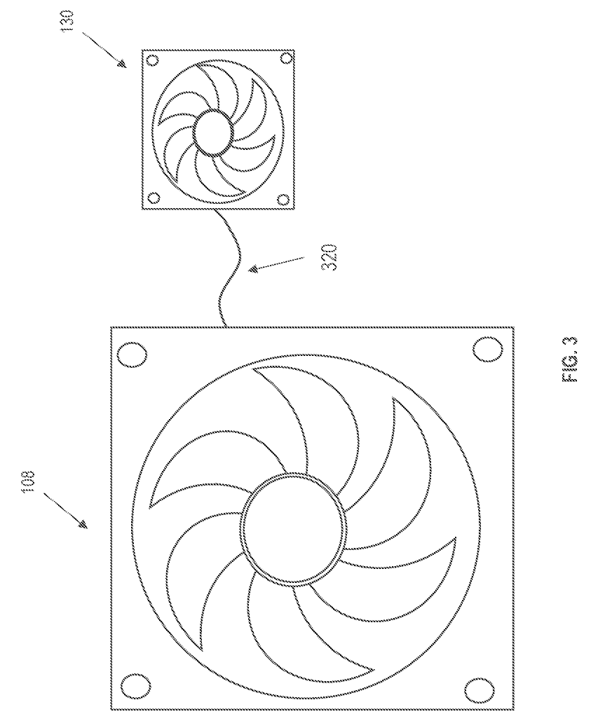

Referring now to FIG. 2 and FIG. 3 simultaneously, components of a cooling system 200 including master fan 108 and slave fan 130 are shown, according to an embodiment of the present disclosure. FIG. 3 provides an example configuration of master fan 108 and slave fan 130. The description of FIG. 2 and FIG. 3 can refer to components shown in FIG. 1.

In an embodiment, master fan 108 is configured to operate based on variations in an operational temperature (T) of heat-generating components 106. Master fan 108 is designed to provide a cooling airflow 10 during the operation of server 100. Specifically, when the operational temperature of heat-generating components 106 is at or above a predefined threshold, master fan 108 is activated to ensure efficient cooling and prevent overheating. The master fan 108 may be controlled by a master fan controller, which may be a stand-alone component or part of the central circuit board 110, PSU 104, or another component of the server 100.

As the demand for enhanced cooling increases in specific components of server 100, additional airflow becomes necessary, particularly during service events (e.g., hot swap events). During service events, components are replaced without powering down the system, and as a result, cover 120 may be raised to provide access to these components. In such cases, simply increasing the speed of master fan 108 may not fully restore optimal cooling or address airflow disruptions caused by the opening of cover 120, which can lead to operational issues. To ensure adequate cooling for heat-generating components 106 during service events, slave fan 130 can be strategically positioned near these components to provide focused airflow and prevent overheating. For example, some heat-generating components 106 such as CPUs, GPUs, and PSUs can become significantly hotter during service events. Disruptions in cooling may exacerbate heat buildup, making it crucial to maintain proper airflow and cooling around such heat-generating components 106 during the service events. In an embodiment, master fan 108 and slave fan 130 can be, for example, a centrifugal fan. Slave fan 130 may be externally and operatively coupled with master fan 108 o. When activated, slave fan 130 provides localized cooling airflow to the adjacent heat-generating component 106, mitigating the risk of overheating. According to an embodiment, slave fan 130 is configured to operate based on an operational speed of master fan 108. Specifically, when the operational speed (i.e., RPM) of master fan 108 meets or exceeds a user-defined speed threshold, slave fan 130 is activated by a slave fan controller 210 (slave fan control module). Slave fan controller 210 may be a stand-alone component or part of master fan 108, slave fan 130, central circuit board 110, PSU 104, a power distribution board (not shown), or another component of server 100. Furthermore, slave fan controller 210 may be disposed on master fan 108, slave fan 130, central circuit board 110, PSU 104, the power distribution board, another component of server 100, or anywhere therebetween.

Slave fan controller 210 can be communicatively coupled with master fan 108, slave fan 130 and with various sensors in server 100, including one or more cover sensors 230. Cover sensors 230 can be positioned at entry points of cover 120 (e.g., on server chassis), such as the case panel or access door. This enables the slave fan controller 210 to manage the activation or deactivation of the slave fan 130 based on the operation of master fan 108 and an open or closed condition of cover 120 during service events. In one or more embodiments, the operational temperature (T) of heat-generating components 106 may increase as a result of factors such as airflow disruptions during service events (e.g., when cover 120 is open). This increase in operational temperature causes the operational speed of master fan 108 to rise as well. Based on the operational speed of master fan 108 meeting or exceeding a threshold value, slave fan controller 210 may activate slave fan 130 to prevent overheating. In an embodiment, one or more cover sensors 230 can detect physical access to the server 100 and can trigger alerts or actions (e.g., enabling the slave fan 130, fan speed adjustments, or system shutdowns) to protect internal components and maintain system security. This configuration allows slave fan 130 to be activated and controlled by interfacing with master fan 108 via slave fan controller 210. Accordingly, the existing master fan 108 may not require modification. As depicted in FIG. 3, slave fan 130 can be operatively connected to master fan 108 through a wiring system 320. For example, in an embodiment, wiring system 320 may include a two-wire hookup, where one wire provides a 5V supply to the slave fan 130 and the other wire is grounded for completing the circuit. Therefore, slave fan 130, as depicted in the figures, is configured to be independently operated based on and/or by master fan 108 via slave fan controller 210. In an embodiment, master fan 108 is communicatively coupled with central circuit board 110 or the power distribution board (PDB) of the server 100, while the slave fan 130 receives power from the master fan 108.

In an embodiment, slave fan 130 can be significantly smaller than master fan 108. For example, master fan 108 may be at least four times larger than slave fan 130. By being significantly smaller than master fan 108, slave fan 130 can be positioned closer to heat-generating components 106, ensuring efficient localized airflow, particularly during service events when targeted cooling is needed.

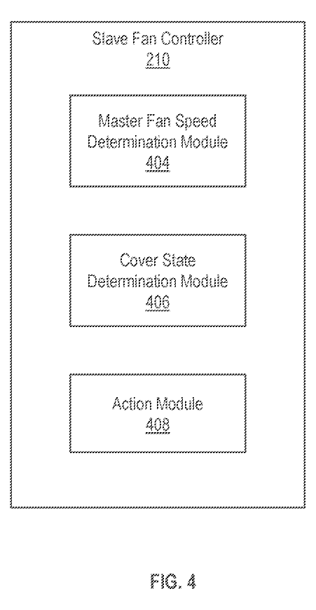

Referring now to FIG. 4, a functional block diagram depicting components of slave fan controller 210 is shown, according to an embodiment of the present disclosure. The description of FIG. 4 can refer to components shown in FIG. 1, FIG. 2, and FIG. 3.

Components of slave fan controller 210 can include a master fan speed determination module 404, a cover state determination module 406, and an action module 408. The master fan speed determination module 404 is configured to determine an operational speed (e.g., RPM, PWM percentage) of the master fan 108 . The cover state determination module 406 is configured to detect whether the cover 120 is in an open or closed state using data from the cover sensors 230. The action module 408 is configured to activate or deactivate (i.e., turning on or off) the slave fan 130 based on inputs from the other modules.

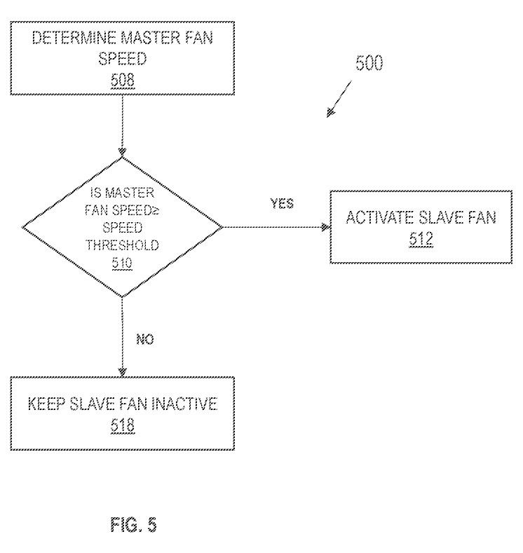

Referring now to FIG. 5, a flowchart illustrating the steps of a computer-implemented method 500 for controlling the operation of slave fan 130 is shown, according to an embodiment of the present disclosure. The computer-implemented method 500 may be performed by slave fan controller 210. The steps described in FIG. 5 can refer to components shown in FIG. 1, FIG. 2, FIG. 3, and FIG. 4.

The method 500 begins at step 508, where a speed of master fan 108 is determined. In step 510, the determined speed of master fan 108 is compared to a user-defined speed threshold level. Particularly, a user-defined speed threshold value (e.g., 95% of full fan speed) is used to evaluate whether the master fan 108 is operating at or near maximum capacity. If the determined speed of master fan 108 meets or exceeds the speed threshold value, the method 500 advances to step 512, where slave fan 130 is activated to provide targeted cooling to a heat-generating component 106.

If at step 510, it is determined that the speed of master fan 108 is below the user-defined speed threshold value, the method 500 continues to step 518, where slave fan 130 remains inactive until the speed of master fan 108 increases or the cooling demands change. An operational speed of the master fan 108 below the user-defined speed threshold value may indicate that additional cooling is not currently needed.

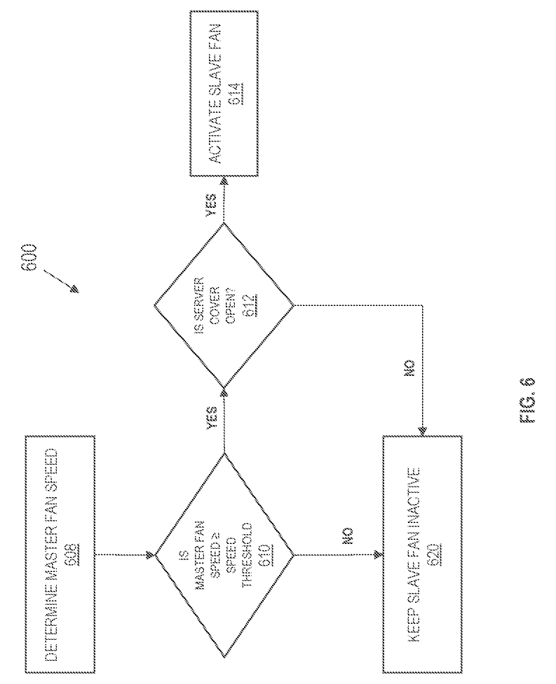

Referring now to FIG. 6, a flowchart illustrating the steps of a computer-implemented method 600 for controlling the operation of slave fan 130 is shown, according to an embodiment of the present disclosure. The method 600 may be performed by the slave fan controller 210. The steps described in FIG. 6 can refer to components shown in FIG. 1, FIG. 2, FIG. 3, and FIG. 4.

The method 600 begins at step 608, where a speed of master fan 108 is determined. In step 610, the determined speed of master fan 108 is compared to a user-defined speed threshold level. Particularly, a user-defined speed threshold value (e.g., 95% of full fan speed) is used to evaluate whether the master fan 108 is operating at or near maximum capacity. If the determined speed of master fan 108 meets or exceeds the speed threshold value, the method 600 advances to step 612, where it is determined whether the cover 120 is open or closed based on input from cover sensors 230. In other words, responsive to determining that the speed of master fan 108 meets the speed threshold value, the slave fan controller 210 may determine if the cover 120 is open.

If the server cover is open the method 600 proceeds to step 614, where slave fan 130 is activated (e.g., placed in an active state, on) to provide targeted cooling to a corresponding heat-generating component 106. If, at step 612, it is determined that cover 120 is closed, the method 600 continues to step 620, where slave fan 130 remains inactive (e.g., off).

If, however, the operational speed of master fan 108, at step 610, is below the speed threshold (e.g., does not meet the speed threshold), the method 600 continues to step 620, where slave fan 130 remains inactive. In other words, responsive to determining that the speed of master fan 108 does not meet the speed threshold value, the slave fan controller 210 may cause the slave fan 130 to be in an inactive state (e.g., off). An operational speed of master fan 108 below the user-defined threshold may indicate that additional/targeted cooling may not be required.

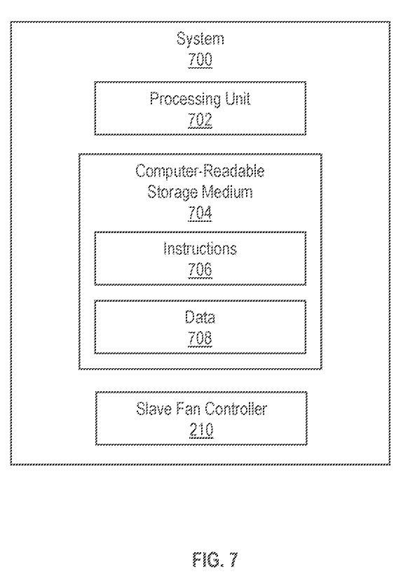

Referring now to FIG. 7, a functional block diagram depicting an example of a system 700 that may be used for controlling an operation of the slave fan 130 is shown, according to an embodiment of the present disclosure.

The system 700 includes at least one processing unit 702, at least one computer-readable storage medium 704, and the slave fan controller 210. The system 700 may be contained within the server 100, partially within the server 100, or communicatively coupled with the server 100.

The processing unit 702 (e.g., one or more of an application processor, central processing unit (CPU), graphics processing unit (GPU), microprocessor, digital-signal processor (DSP), or controller) executes instructions 706 (e.g., code) stored within the computer-readable storage medium 704 (e.g., a non-transitory storage devices such as a hard drive, solid-state drive (SSD), flash memory, random access memory (RAM), read-only memory (ROM), erasable programmable read-only memory (EPROM), or electrically erasable programmable read-only memory (EEPROM)) to cause the system 700 to perform the techniques described herein. The instructions 706 may be part of an operating system and/or one or more applications of the system 700.

The instructions 706 cause the processing unit 702 to act upon (e.g., create, receive, modify, delete, transmit, or display) the data 708 (e.g., application data, module data, sensor data, or I/O data). Although shown as being within the computer-readable storage medium 704, portions of the data 708 may be within a random-access memory (RAM) or a cache of the system 700 (not shown). Furthermore, the instructions 706 and/or the data 708 may be remote to the system 700.

The slave fan controller 210 (or portions thereof) may be comprised by the computer-readable storage medium 704 or be a stand-alone component (e.g., executed in dedicated hardware in communication with the processing unit 702 and computer-readable storage medium 704). For example, the instructions 706 may cause the processing unit 702 to implement or otherwise cause the slave fan controller 210 to perform the actions discussed above.

The system 700 may also contain a communication system (not shown) that may be any wired or wireless communication system configured to communicate data over one or more connections or networks. For example, the communication system may be configured to communicate data between the system 700 and a separate device (e.g., slave fan 130 if the system 700 is not implemented within the server 100).

Example 1: A server comprising: a master fan configured to generate airflow through the server; a slave fan disposed proximate a heat-generating component; and a slave fan controller communicatively coupled with the master fan and the slave fan and configured to control an operation of the slave fan based on an operation of the master fan.

Example 2: The server according to example 1, wherein the slave fan controller is configured to control the slave fan based on an operational speed of the master fan.

Example 3: The server according to example 2, wherein the slave fan controller is configured to activate the slave fan when the operational speed of the master fan meets a threshold level.

Example 4: The server according to example 1, wherein the master fan is communicatively coupled with a motherboard or a power distribution board (PDB) of the server.

Example 5: The server according to example 1, wherein the slave fan receives power from the master fan.

Example 6: The server according to example 1, further comprising: a cover; and a cover sensor configured to detect whether the cover is open or closed.

Example 7:The server according to example 6, wherein: the slave fan controller is communicatively coupled with the cover sensor; and the slave fan controller is configured to control the slave fan based on an operational speed of the master fan and whether the cover is open or closed.

Example 8: The server according to example 1, wherein the master fan is more powerful than the slave fan.

Example 9: A computer-implemented method for controlling a slave fan of a server, the method comprising: determining, by a slave fan controller that is separate from a master fan controller, an operational speed of a master fan of the server that is controlled by the master fan controller; and controlling, by the slave fan controller and based on the operational speed of the master fan, the slave fan.

Example 10: The computer-implemented method according to example 9, wherein the controlling comprises not activating the slave fan responsive to determining that the operational speed of the master fan does not meet a threshold value.

Example 11: The computer-implemented method according to example 9, wherein the controlling comprises activating the slave fan responsive to determining that the operational speed of the master fan meets a threshold value.

Example 12: The computer-implemented method according to example 11, wherein the activating the slave fan comprises causing the slave fan to draw power from the master fan.

Example 13: The computer-implemented method according to example 9, wherein the master fan controller is part of a motherboard or a power distribution board (PDB) of the server.

Example 14: The computer-implemented method according to example 9, further comprising determining, by the slave fan controller, whether a cover of the server is open or closed, wherein the controlling is based further on whether the cover of the server is open or closed.

Example 15: The computer-implemented method according to example 14, wherein the controlling comprises activating the slave fan responsive to determining that the operational speed of the master fan meets a threshold value and that the cover of the server is open.

Example 16: The computer-implemented method according to example 9, wherein the master fan is larger than the slave fan.

Example 17: A slave fan controller configured to be disposed within a server and comprising a processing unit configured to: determine an operational speed of a master fan of the server; and control, based on the operational speed of the master fan, a slave fan of the server, wherein: the master fan is configured to move air through the server; and the slave fan is configured to move air proximate a heat-generating component of the server.

Example 18: The slave fan controller according to example 17, wherein the slave fan controller is configured to be disposed communicatively between the master fan and the slave fan.

Example 19: The slave fan controller according to example 18, wherein the slave fan controller is configured to be disposed on the master fan.

Example 20: The slave fan controller according to example 17, wherein the processing unit is further configured to: determine whether a cover of the server is open or closed; and control the slave fan based further on whether the cover of the server is open or closed.

Embodiments of the present disclosure may be a system, a method, and/or a computer program product. The computer program product may include a computer readable storage medium (or media) having computer readable program instructions thereon for causing a processor to carry out aspects of the present disclosure.

Computer readable program instructions described herein may be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the "C" programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, may be implemented by computer readable program instructions.

These computer readable program instructions may be provided to a processor of a general-purpose computer, a special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that may direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus, or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, a segment, or a portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, may be implemented by special purpose hardware-based systems that perform the specified functions or acts or carry out combinations of special purpose hardware and computer instructions.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

The corresponding structures, materials, acts, and equivalents of all means or step plus function elements, if any, in the claims below are intended to include any structure, material, or act for performing the function in combination with other claimed elements as specifically claimed. The description of the present disclosure has been presented for purposes of illustration and description but is not intended to be exhaustive or limited to this disclosure in the form disclosed. Many modifications and variations will be apparent to those of ordinary skill in the art without departing from the scope and spirit of this disclosure. The various embodiments were chosen and described in order to best explain the principles of this disclosure and the practical application, and to enable others of ordinary skill in the art to understand this disclosure for various embodiments with various modifications as are suited to the particular use contemplated.

Spatially relative terms, such as “inner,” “outer,” “beneath,” “below,” “lower,” “above,” “upper,” “top,” “bottom,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90 degrees or at other orientations) and the spatially relative descriptors used herein interpreted accordingly.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A server comprising:
a master fan configured to generate airflow through the server;
a slave fan disposed proximate a heat-generating component in the server; and
a slave fan controller communicatively coupled with the master fan and the slave fan and configured to control an operation of the slave fan based on an operation of the master fan.

2. The server according to claim 1, wherein the slave fan controller is configured to control the slave fan based on an operational speed of the master fan.

3. The server according to claim 2, wherein the slave fan controller is configured to activate the slave fan when the operational speed of the master fan meets a threshold level.

4. The server according to claim 1, wherein the master fan is communicatively coupled with a motherboard or a power distribution board (PDB) of the server.

5. The server according to claim 1, wherein the slave fan receives power from the master fan.

6. The server according to claim 1, further comprising:
a cover; and
a cover sensor configured to detect whether the cover is open or closed.

7. The server according to claim 6, wherein:
the slave fan controller is communicatively coupled with the cover sensor; and
the slave fan controller is configured to control the slave fan based on an operational speed of the master fan and whether the cover is open or closed.

8. The server according to claim 1, wherein the master fan is more powerful than the slave fan.

9. A computer-implemented method for controlling a slave fan of a server, the method comprising:
determining, by a slave fan controller that is separate from a master fan controller, an operational speed of a master fan of the server that is controlled by the master fan controller; and
controlling, by the slave fan controller and based on the operational speed of the master fan, the slave fan.

10. The computer-implemented method according to claim 9, wherein the controlling comprises not activating the slave fan responsive to determining that the operational speed of the master fan does not meet a threshold value.

11. The computer-implemented method according to claim 9, wherein the controlling comprises activating the slave fan responsive to determining that the operational speed of the master fan meets a threshold value.

12. The computer-implemented method according to claim 11, wherein the activating the slave fan comprises causing the slave fan to draw power from the master fan.

13. The computer-implemented method according to claim 9, wherein the master fan controller is part of a motherboard or a power distribution board (PDB) of the server.

14. The computer-implemented method according to claim 9, further comprising determining, by the slave fan controller, whether a cover of the server is open or closed, wherein the controlling is based further on whether the cover of the server is open or closed.

15. The computer-implemented method according to claim 14, wherein the controlling comprises activating the slave fan responsive to determining that the operational speed of the master fan meets a threshold value and that the cover of the server is open.

16. The computer-implemented method according to claim 9, wherein the master fan is larger than the slave fan.

17. A slave fan controller configured to be disposed within a server and comprising a processing unit configured to:
determine an operational speed of a master fan of the server; and
control, based on the operational speed of the master fan, a slave fan of the server,
wherein:
the master fan is configured to move air through the server; and
the slave fan is configured to move air proximate a heat-generating component of the server.

18. The slave fan controller according to claim 17, wherein the slave fan controller is configured to be disposed communicatively between the master fan and the slave fan.

19. The slave fan controller according to claim 18, wherein the slave fan controller is configured to be disposed on the master fan.

20. The slave fan controller according to claim 17, wherein the processing unit is further configured to:
determine whether a cover of the server is open or closed; and
control the slave fan based further on whether the cover of the server is open or closed.
